(19) United States
(12) Patent Application Publication
(10) Pub. No.: US 2008/0007268 A1
(43) Pub. Date: Jan. 10, 2008

(54) Direct physical generator of justice or injustice

(76) Inventor: Bret Bernard Cummings, El Segundo, CA (US)

Correspondence Address: Bret Cummings, P.O. Box 485, El Segundo, CA, 90245-0485, US

(21) Appl. No.: 11/441,685

(22) Filed: May 26, 2006

(51) Int. Cl. G01R 29/12

(52) U.S. Cl. 324/457

(57) ABSTRACT

This is a machine that creates modulated oscillations of attracting electrostaticly charged bodies so as to directly create time-space forms of acceleration of force that are intended to be conscious, and more particularly, to be sensations of justice and injustice. Justice consists of sensations of intent that are satisfied in direct proportion to the rightfulness of said intent, and frustrated in direct proportion to the wrongfulness of said intent. Injustice is deviation from those accurate proportions. Rightful intent consists of waves that increasingly decelerate relative to their unmodified form during their acceleration phase and deceleration phase, leading to smaller waves, whereas wrongful intent consists of waves that increasingly accelerate relative to their unmodified form during their acceleration phase and/or deceleration phase, leading to larger waves.

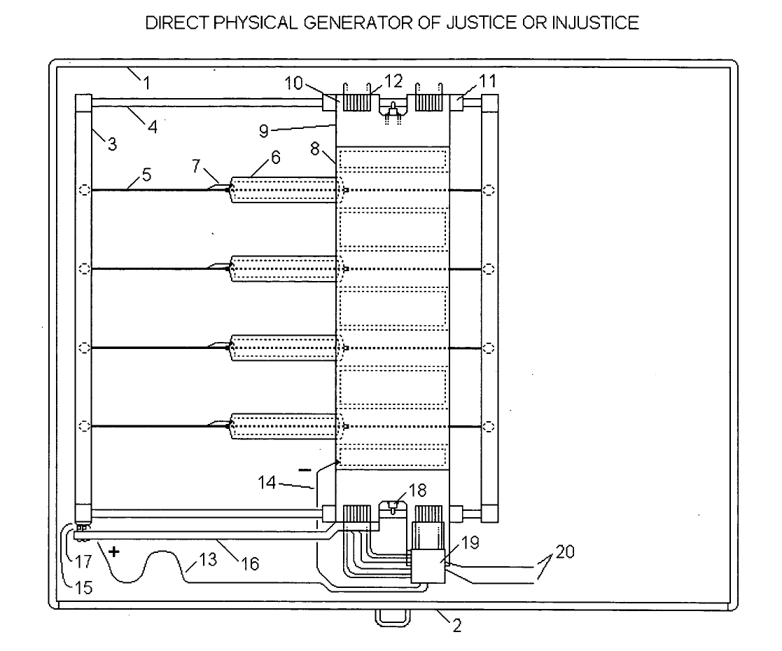

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

1. Field or Fields of the Invention

electrophysiology, physics, and a-priori logic

2. Background Principles

It is known that specific forms of electrical oscillations within neurons constitute specific sensations. The physics of the electrical oscillations in neurons consists of an oscillation between force and speed, as also occurs in nearly everything else that moves, namely photons, sound waves, vibrating particles, and elliptical gravitational orbits. Even circular orbits possess a break-even exchange of speed and force, indicating that they roughly fall into this classification as well. Photons and neurons also have in common the property of constant acceleration, due to the distance between the forces being precisely directly proportional to the strength of the forces, in a given oscillation, though that property does not necessarily affect conscious sensation.

A-priori cosmology dictates that the universe is a static infinite solution set of all possible absolute forms. Absolute forms possess the 2 properties of being equally real and being separate, which are precisely the 2 properties which define consciousness, meaning that the universe is fundamentally composed of consciousnesses. The oscillation between force and speed, when oriented by the dimension of time, possesses such mathematically absolute form. The natural path of an oscillation from it's state of potential energy is usually roughly the path of a sine wave, and varies to some degree based upon the degree to which the forces naturally cancel out. The presence of that natural path indicates that there is a force that moves such waves toward states of smooth oscillations and away from states of disrupted oscillations. That is the conscious force which moves toward undisrupted sine wave states of pleasure and away from disrupted sine wave states of suffering. When multiple oscillations are oriented in the same direction as the adjacent oscillation, and in close enough vicinity to the adjacent oscillations for the conscious force to effect them, then the oscillations synchronize into a net oscillation that moves toward the state of an undisrupted sine wave and away from the state of a disrupted sine wave. The conscious force not only motivates conscious attention and action in conscious animals (vertebrates and cephalopods, the brains of which exhibit slow-wave activity), but also causes the activity of lasers and masers, the astrophysical wolf effect, tuning forks, and the commonality of stable circular astronomical orbits despite the improbability of such orbits. The conscious force might also be responsible for the similar rotational speed of the interior and exterior areas of galactic disks, as well as the fact that galaxies do not fly apart despite their rotational speed.

There is a distinction between soft deviations from the natural path and sharp deviations from the natural path. Soft deviations still generally follow a pathway, such that the intent of the wave is altered rather than frustrated, whereas sharp deviations are breakages in a pathway, such that they result in frustrated intent rather than altered intent. Deviations that are intermediate between sharp and soft are intermediate between an altered intent and a frustration of the previous intent, such that they are internally conflicted.

Next there is the matter of justice and injustice. Justice is the state in which the rightful intent versus wrongful intent of a conscious sensation is equal to it's degree of pleasurable satisfaction verses painful frustration, respectively. Injustice is deviation from that state, with greater injustice being greater deviation. Pleasure consists of smooth waves that are equal to or similar to a sine wave, whereas pain consists of waves that begin as smooth waves but are sharply distorted far off of their natural path before the sine wave is complete, such that the wave is frustrated. The farther the deviation from the sine wave, the stronger the suffering. Physiological properties of neurological receptors of rightful intent and wrongful intent indicate that rightful intent corresponds to progressive deceleration of the oscillation relative to the natural path, whereas wrongful intent corresponds to progressive acceleration of the oscillation relative to the natural path. A waveform that increasingly decelerates relative to the natural path moves toward greater fineness, accuracy, and rightness, indicating rightful intent, whereas a waveform that increasingly accelerates relative to the natural path moves toward greater crudeness, inaccuracy, and wrongness, indicating wrongful intent. Progressive relative deceleration of an oscillation may be called ‘inward deviation’, whereas progressive relative acceleration of a waveform may be called ‘outward deviation’. If such inward and outward deviations were applied to circular force orbits rather than oscillations, then they would produce inward spirals and outward spirals, respectively. Force oscillations consist of 2 phases, those being a phase of acceleration while force is cancelled, and a phase of deceleration while force is created. A wave grows progressively smaller in it's aspect of amplitude when it's acceleration phase is increasingly decelerated such that it gains less speed, and the wave grows progressively smaller in it's aspect of wavelength when it's deceleration phase is increasingly decelerated such that it terminates quicker, indicating that both of those 2 phase modifications are essential to complete rightful intent, whereas both of the opposite phase modifications are essential to complete wrongful intent. It is notable that all phase modifications must consist of one of the 2 properties of inward deviation or outward deviation, but of course such modifications can be mixed throughout the length of the waveform, and to different degrees of sharpness, such that a wide range of unique forms can be produced which constitute neither rightful intent nor wrongful intent.

Justice thus consists of waves of a relatively decelerating acceleration phase and a relatively decelerating deceleration phase which are smooth and do not deviate far from a sine wave, and also waves of a relatively accelerated acceleration phase and a relatively accelerated deceleration phase which have a sharp inward obstruction in each of the 2 phases. It is notable that if an oscillation wave is deviated inward or outward to too far a degree, then it can not be pleasurable no matter how otherwise unobstructed it is, because it still deviates too far from the natural path. Therefore, it is inherently unjust for waves to be deviated too far inward, regardless of whether they are further obstructed or not. There must be a break-even point in which an otherwise unobstructed deviating wave deviates away from the natural path in either direction to a degree that it is precisely neutral between pleasure and pain.

### Comparison to Prior Art:

Before the implementation of this invention, only the following methods of producing justice and injustice exist. Justice is theoretically deliberately created by the criminal justice system and other systems of reward and punishment, and even then it is only crude and reactive, and serves not so much to create justice as to keep society functioning. Some laws deliberately serve to create injustice. Justice and injustice both occur in large amounts deliberately by personal actions and non-deliberately by happenstance. This machine, in contrast, creates justice or injustice proactively, purely, in large quantities, and, most distinctively, it does so in a direct physical manner that bypasses any living bodies, brains, and the environmental input thereto.

### BRIEF SUMMARY OF THE INVENTION

This machine creates modulated oscillations of attracting electrostaticly charged bodies, so as to directly physically create forms of acceleration of force that are intended to be conscious, and more particularly, to be sensations of justice or injustice. Justice consists of sensations of intent that are satisfied in proportion to the rightfulness of said intent, and frustrated in proportion to the wrongfulness of said intent. Rightful intent consists of waves that increasingly decelerate relative to their unmodified form during their acceleration phase and deceleration phase, leading to smaller waves, whereas wrongful intent consists of waves that increasingly accelerate relative to their unmodified form during their acceleration phase and/or deceleration phase, leading to larger waves.

### BRIEF DESCRIPTION OF THE DRAWING OR DRAWINGS

The drawing is a top view. The following are the components, as noted on the drawing of the machine:

1. thick rectangular-prismatic acrylic glass protective casing that covers the machine in all 3 dimensions

2. thick acrylic glass hatch with bracing latch, that can open the casing for repair in case of malfunction

3. plate of insulated stainless steel framework

4. long cylindrical permanent magnet, encased in stainless steel for structural support

5. thick nylon cord

6. positively-charged cylindrical aluminum rod encased in thick rubber

7. branch positive charging wire with a diode where it meets the positive rod

8. immobile negatively-charged aluminum grid encased in thick rubber, with large cylindrical holes through it

9. structural component that is composed of non-conducting solid strong plastic

10. highly lubricated holes for movement

11. rubber stopper in case of excessive movement

12. electromotive coil with wires leading from it

13. main positive charging wire that is loose and moves with the mobile positive grid

14. negative charging wire with a diode where it meets the negative grid

15. aluminum plate contact

16. brace for electrode contacts

17. wires with carbon brush electrodes

18. latching mechanism

19. control circuit

20. wires to a power source

The dashed lines in the drawings indicate internal structure that is not visible on the surface. Particularly, they show the separation between aluminum and it's rubber insulation, the holes in the immobile aluminum grid, the nylon cord through the aluminum rods, the segments of the aluminum rods and nylon cords that are hidden in the holes in the immobile aluminum grid, and the vertical stainless steel bars of the end braces.

### DETAILED DESCRIPTION OF THE INVENTION

### Application:

Unlike almost all inventions, this machine does not serve humans or animals, but is an end in it's own right. Generators may be placed nearly anywhere in which they do not interfere with other important functions nor are themselves prone to interference. Places that have good potential for solar power may be preferable. It is unlikely that this machine will be manufactured and utilized on a large scale in the near future.

### Description of the Composition and Function of the Invention:

This invention utilizes electrostatic attractive force to create oscillations, and those oscillations are modulated so as to directly create specific forms of acceleration of force. The term ‘acceleration’, when used here in the term ‘forms of acceleration of force’, includes both acceleration and deceleration of relative speed, as it refers to acceleration in the absolute sense rather than the relative sense. The acceleration forms produced by this invention are similar to the electrostatic acceleration forms produced by neurons of conscious brains. For the machine, the stronger the charge and the faster the oscillations, the more powerful the conscious sensations, and the more likely it is that the different charged oscillating components will synchronize into a single consciousness.

The force-carrying components may be electrically-charged metal, electrically-charged non-metallic substance, or containers of ions. Electrically-charged metal is the preferable form, which is used in this description.

There are 2 central components of the machine, which are the immobile charged component and the mobile charged component. The mobile charged component moves relative to the immobile charged component. The immobile charged component may either be negatively charged or positively charged. In this example description, the immobile charged component is negatively charged and the mobile charged component is positively charged.

The oscillation is perpendicular to the pull of gravity, so as to eliminate any interference from gravity. The generators do not have any components that are dependent upon gravity, but gravity still poses a threat. If the machine were tilted wrongly, gravity would pull on the mobile charged component relative to the immobile charged component, thus interfering with the oscillation. The machine can optionally implement a powerful gyroscope or a weak gyroscope combined with other stabilizing mechanisms, if it is useful to do so. That would allow them to function in gravitationally unstable environments such as on the surface of a body of water, under the surface of a body of water, and in outer space.

The entire machine is enclosed in a complete 3-dimensional rectangular prismatic protective casing that is durable but transparent, such as thick acrylic glass. That allows the machine to be monitored for malfunction while also protecting the machine from interference by various physical objects, people, animals, and weather. The casing should contain a hatch on one of the sides that is made of the same material as the rest of the casing. The hatch should be as large as the machine itself, so as to be able to easily access the machine for repair in case of malfunction. If the hinge of the hatch is on the top edge, then the hatch should be able to rotate all the way over the top so as to sit on the top surface of the casing.

There are preferably one or more deep cycle batteries within the casing that are fused to the bottom surface of the casing, though the machine can work without them. The deep cycle batteries would serve to give the machine a source of stored power in cases of a non-constant power supply. The machine can be powered by being attached to an electrical grid, or by being attached to an autonomous source of power such as solar panels and/or small wind turbines. Attachment to an autonomous source of power is preferable.

There are positively-charged aluminum rods encased in thick rubber electrical insulation that oscillate through cylindrical holes in a negatively-charged aluminum grid encased in thick rubber electrical insulation. The charge-holding metal, as well as the metal of the wires of the machine, is aluminum. The thick rubber electrical insulation prevents plasma bolts of charge from passing between the metals of opposite charge. The negatively-charged grid has a thickness that is equal to the length of the rods, and when the rods are at their maximum distance from the grid, the ends of the rods are adjacent to the outer border of the cylindrical holes in the grid, rather than going beyond them. That allows the machine to imitate the function of a neuron or photon, such that, as the rods move into the grid, the attracting force decreases, just as in neurons and photons in which, as the charges move toward each other, the attracting force decreases.

The positively-charged rods are all parallel to, and move parallel to, each other. They are also all equally spaced. There may be a single row of rods or multiple rows.

Attached to the immobile grid are solid plastic structural pieces. The plastic structural pieces are attached to magnetic rods that ultimately control the motion of the positively-charged rods relative to the negatively-charged grid. Strong plastic is used because it is an electrical insulator, it is easily shapable, and it is unelastic, unlike rubber. The plastic structural pieces have lubricated movement holes and electromotive coils. The holes serve to hold the rods in place and the coils serve to move the rods. It is the timed force applied to the electromotive coils, relative to the motion of the positively-charged rods, that ultimately determines the nature of the oscillation forms produced by the machine. Obviously, all of the electromotive coils function in unison. The wires that lead to the electromotive coils may be called ‘the electromotive coil wires’.

A magnetic rod consists of a permanent magnet encased in a stainless steel tube for structural support. There may be 4 magnetic rods altogether, one on each corner, which is the minimum, or there may be more rods along the border of the negatively-charged grid, along with their movement holes and electromotive coils. There may also be purely structural non-magnetic hollow stainless steel rods around the border, which use movement holes but no electromotive coils. Purely structural rods however can not replace any of the minimum 4 magnetic rods that are situated on the corners.

All of the magnetic rods are attached to the same 2 end braces. The end braces are composed of a square grid of hollow stainless steel bars, with thicker hollow stainless steel bars forming the outer border of the brace. The entire brace is covered in a relatively thin layer of rubber electrical insulation. The end braces are attached to, and simultaneously move, many thick nylon cords. The nylon cords are in turn attached to the positively-charged rods. Thus, the electromotive coils that move the magnetic rods move the positively-charged rods relative to the negatively-charged grid.

The reason that the end braces are composed of a grid of hollow steel bars is that the end braces must be strong, light-weight, and aerodynamic, so that the end braces will move easily. The positively-charged aluminum rods are also somewhat tapered and rounded on their ends for aerodynamics.

The negatively-charged grid and each of the positively-charged rods are charged by a charging wire. Each charging wire that attached to a charge-holding body has a diode where it attached to said body, so as to prevent backward flow of charge. The positive charging wires that attach to the positively-charged rods branch out from a main positive charging wire. There is thus a single main positive charging wire and a single negative charging wire. The positive charging wires that branch our from the main positive charging wire may be called ‘the branch positive charging wires’. The branch positive charging wires are taped to the thick nylon cord. The branch positive charging wires also have extra thick rubber insulation because they pass through the holes in the negatively-charged grid. A Van de Graaff type charging machine may be used to assist in the charging of the positive and negative charged bodies.

There are is a brace made of stainless steel tubes covered with relatively thin rubber insulation. It is not to be confused with the end braces. This brace may be called ‘the electrode brace’. This brace is attached to the side of the plastic structural pieces, on the outside of the magnetic rods. On the brace are one or more pairs of carbon brush electrodes that are aligned with the side of where the end braces pass by during their motion. There is an aluminum plate on the side of the end braces. The aluminum plate has convex edges so that it projects from the side. As the aluminum plate moves with the end braces, at some point it will form a complete circuit with the carbon brushes. There is at least one pair of electrodes, which is situated such that a complete circuit is formed when the mobile grid is at it's maximum outward extension. However, there may be many more pairs of electrodes along the length of the path of the end brace. The wires that lead to the electrodes may be called ‘the electrode wires’. The electrode wires are taped to the electrode brace so as not to interfere with any other components.

There is a latching mechanism that is adjacent to each of the magnetic rods that is embedded into the plastic structural pieces. There are notches in the magnetic rods, which work with the latches. There is only one notch along the length of each rod, at the same position on each rod, which is situated such that, when it is latched, the mobile grid is in it's position of maximum extension from the immobile grid. The latching mechanism serves to hold the mobile grid in place when there is a power shortage. The latch itself is composed of stainless steel, and is embedded deep in the plastic structural piece to which it is attached, such that it will not break under pressure from it's associated magnetic rod. The latching piece itself is spring-loaded, and is bordered on the side by spring-loaded notches that are flat on the inside and inclined on the outside, such that when the latching piece is pulled back, it snaps in place. The latching mechanism is electronic, such that it uses internal electromotive coils and permanent magnets attached to the latching piece and notch pieces, so as to pull back the latching piece or to pull back the notches, to unlatch or latch the magnetic rods, respectively. 4 wires lead from each latch. The wires that lead from the latches may be called ‘the latch wires’.

The main positive charging wire and the negative charging wire both run along the ground, below the magnetic rods and the electrode brace, so as not to interfere with them. Altogether, there are many wires that lead from the machine, 4 types of wires in all. There are the 2 main charging wires, the electromotive coil wires, the electrode wires, and the latch wires. All of those wires lead to a control circuit that is attached to the plastic structural pieces. In turn, there are 2 wires that lead from the control circuit to the power source. The electromotive coil wires and latch wires that originate from the side of the machine opposite to the control circuit go over the top of the machine, so as not to interfere with the motion of the mobile grid, and said wires are taped to the insulating rubber on the top of the machine to hold them in place. The control circuit has multiple functions. First, it regulates the degree of charge of the charged bodies. Second, it determines the oscillation form of the moving charged bodies by controlling the degree of power over time that is sent to the electromotive coils, and by responding to feedback from the electrodes so as to ensure that the oscillations have the right timing. Third, it latches the mobile grid when there is a shortage of power.

### Method of Manufacture:

The basic components from which this device is composed can be manufactured by the usual methods by which such components are manufactured, such as casting, polymerization, and circuit board printing. Description of the component assembly is as follows.

The thick acrylic glass casing should be manufactured separately from the rest of the machine, and should be the last component that is added to the main part of the machine except for the power wires, and possibly certain accessories such as deep cycle batteries, solar panels, or a gyroscope. The acrylic glass casing can be produced mostly from a single piece of cast acrylic glass, with the exception of the hatch, or from multiple plates that are welded together or fused together with industrial adhesive. When the casing and the main part of the machine are both completed, the center of the bottom surface of the acrylic glass is covered with industrial adhesive, and the main part of the machine is slid into the case on lubricated rails, to fall in place onto the adhesive. The bottom plate of the acrylic glass casing is molded with upraised areas on the corners of where the main part of the machine should sit, so as to hold it in the correct place while the adhesive dries. Unless the machine runs exclusively on internal solar panels and/or cold fusion generators, backed up by deep-cycle batteries, then external power wires are required, such that 2 small holes must be bored through the casing, through which the wires are put. It is very unlikely that internal solar panels can cover sufficient surface area to fully power the machine unless the casing is made much larger than the machine itself, and cold fusion generators are not produced on a commercial scale, so the use of external power wires combined with internal back-up deep-cycle batteries is the most likely scenario.

Aside from the casing, there are 2 main components of the machine, which are the immobile component and the mobile component. Each of those 2 major components should be manufactured separately before being combined together, except that the mobile component should have one of it's end braces unattached, so as to allow the mobile component to be inserted into the immobile component, after which the unattached end brace is then attached. After that end brace is attached, the main positive charging wire of the mobile component is attached to it's appropriate place on the control circuit via a tight plug-in aluminum contact. The 2 main components, being assembled separately, can of course be assembled at the same time or otherwise in no particular order.

The following is the assembly of the mobile component. The end braces of the mobile grid are created by cutting semicircular groves out of stainless steel tubes so as to allow them to interlock at 90 degrees, then welding the joints together. The grooves go half way through the steel bars, as that is the deepest that the bars can be joined without having overhanging metal. The cross-hatching bars of the end braces are arranged such that the center of their junctions will be aligned with the center of the cylindrical holes in the immobile aluminum grid. The outer frame of an end brace is composed of thicker stainless steel tubes, with holes cut into them into which both the smaller stainless steel tubes and the magnetic rods insert, and are subsequently welded in place. The end brace should be fully created before the magnetic rods are inserted into it's frame, but of course one of the end brace frames can not have the magnetic rods inserted until the entire mobile component is attached to the immobile component. To complete the end braces, they are dipped in liquid rubber for electrical insulation, though they do not require as much insulation as the charged components. The magnetic rods are created by creating long cylindrical permanent magnets and hollow stainless steel tubes that are just large enough for the permanent magnets to slide into. Any space between the permanent magnets and the tubes that they are in can be filled with graphite powder. Brazing is then applied to the ends of the tubes to hold the permanent magnets in. Next, a square-edged notch is cut into each magnetic rod at the appropriate place, so as to allow the latching mechanism to work. After the end braces are created, the magnetic rods are attached to one of them. The aluminum rods are molded with a tight female plug into which a charging wire can attach. The female aluminum plug is on one of the ends of the rod, rather than on the side. The aluminum rods are covered with industrial adhesive and the 2 halves of the thick rubber insulation are placed over them, and the 2 halves are held together with industrial adhesive. One of the halves of the rubber insulation must contain a small hole in the location of the aluminum plug, into which a charging wire and it's diode can tightly fit. The hole through the aluminum rods and their rubber insulation, through which the nylon cord goes, is preferably created when the aluminum and rubber is molded, rather than being bored afterward. The thick nylon cord is then pulled through the hole by having a smaller cord attached to an end which is lowered through the hole by gravity, or by a long needle-like implement that is attached to an end of the nylon cord. The nylon cord is given enough length on both ends to attach to the end braces, and then the nylon cord is tied in knots on the 2 ends of the aluminum rod to hold the rod in place, and the knots are sealed in place with industrial adhesive. Such knots are most likely simple overhand knots or double overhand knots. Next, one of the ends of the thick nylon cord is tied tightly to a 90-degree junction in one of the end braces, and sealed in place with industrial adhesive, and after that, any excess cord is cut off. As for the type of knot that should be used at the junction, the cord should pass over the upper left corner of the junction, cross diagonally behind the junction and come back out on the lower right, loop to the left around the cord and then pass over the upper right of the junction, cross diagonally behind the junction and come back out on the lower left, loop to the right around the cord and over the diagonal segment on the upper right and under the diagonal segment on the upper left, and then the knot is tightened to the junction, such that the cord is held tightly at the center of the junction. Of course, the cords can only be tied to one of the braces until the mobile component is inserted into the immobile component. The female aluminum plugs on the rods must all be on the side of the end brace to which they are attached first. Next, the ends of the charging wires with their diodes are inserted into the plugs on the ends of the aluminum rods, and then the branch charging wires are taped tightly to the thick nylon cord, and then, further down the wire, they are tightly taped to the end brace. The tape must be of a highly adhesive and long-lasting type, such that it will not come off due to minor challenges such as time or chronic exposure to moisture and/or moderate heat (heat below 100 degrees celsius).

The following is the assembly of the immobile component. The immobile aluminum grid is molded with a tight female plug into which the negative charging wire can attach. The immobile aluminum grid is covered with a thin layer of industrial adhesive, and then the 2 halves of the thick rubber insulation covering are slid over the immobile aluminum grid. One of the halves of the rubber insulation must contain a small hole in the location of the aluminum female plug, into which the negative charging wire and it's diode can tightly fit. Next, the ends of the immobile grid are covered with industrial adhesive, after which the large plastic structural components are attached. Next, the other components are attached to the plastic structural pieces, in no particular order. The electrode brace, the latches, and the control circuit should each be fully manufactured separately before they are attached to the plastic structural pieces. The electromotive coils, the fully-assembled electrode brace, the fully-assembled latches, and the fully-assembled control circuit are put in their places on the plastic structural pieces and further secured in place with industrial adhesive. The electromotive coils must be secured to the plastic structural pieces by a non-corrosive adhesive, so as not to risk penetrating through the rubber insulation and damaging the metal wire. Next, the wires from the electromotive coils and latches on the opposite side of the control circuit are drawn moderately tightly over the top of the immobile component and taped in place onto the top of the rubber insulation of the aluminum grid, such that they hang over the same side of the machine that the control circuit is on. The tape is of the same type that is used to tape the positive charging wires to the nylon cords and end brace. Next, the negative charging wire, the electrode wires, the electromotive coil wires, and the latch wires are attached to their appropriate places on the control circuit via tight plug-in aluminum contacts. The control circuit also has tight plug-in aluminum contacts to which power wires attach. Of course, the power wires are attached after the complete machine is attached into it's casing.

I claim the following as my invention:

1. any apparatus which creates oscillations of attracting electrostaticly charged bodies, in which the oscillations are modulated so as to increasingly decelerate relative to their unmodified form during their acceleration phase and deceleration phase, leading to smaller waves and indicating rightful intent, and/or to increasingly accelerate relative to their unmodified form during their acceleration phase and/or deceleration phase, leading to larger waves and indicating wrongful intent,
in which those modulated oscillations are disrupted or undisrupted to any degree by deviations far off the natural path of the wave
